(19) United States
(12) Patent Application Publication
(10) Pub. No.: US 2005/0178331 A1
(43) Pub. Date: Aug. 18, 2005

(54) Electrode assembly and method for producing an electrode plate

(76) Inventor: Lawrence C. Fourtner, Boise, ID (US)

Correspondence Address: Joseph W. Holland;Holland & Thiel, PC, PO Box 1840, Boise, ID, 83701-1840, US

(21) Appl. No.: 10/779,019

(22) Filed: Feb. 13, 2004

(51) Int. Cl. C23C 16/00

(52) U.S. Cl. 118/723 E

(57) ABSTRACT

An electrode plate including an anodizing pattern having selected non- anodized surfaces. In one preferred embodiment of the invention, the electrode plate includes an electrode plate having an electrode plate interface surface, a seat formed in the interface surface with the electrode plate including an anodized surface pattern having selected non-anodized surfaces.

### BACKGROUND OF THE INVENTION

1. Field of Invention

The present invention relates to electrode assemblies used in producing a plasma in reactor vessels and, more specifically, to an electrode assembly including an anodized coating and a method for producing an electrode plate including selectively anodized surfaces.

2. Background of the Invention

A problem has been observed in the use of various electrodes employed plasma environments in the manufacture of chip wafers. Particularly, certain electrodes exhibit a problem with sealing integrity at the location of an o-ring groove formed near the perimeter of the electrode mounting ring. More particularly, it has been observed that anodizing the o-ring groove of an electrodes assembly provides a site that may be prone to vacuum leaks, transmigration of process gasses, undesirable electrical properties and problems attendant to the propagation of cracks within the anodized coating.

Manufacturing standards for electrodes used in various process environments typically specify acceptable surface roughness values for o-ring groove surfaces, including the bottom surface of the o-ring groove, in order to assure proper sealing of the o-ring against vacuum conditions and various process gases. In order to produce a surface having a specified surface roughness value following anodizing, it is common to first prepare the surface finish prior to anodizing that has an even smoother finish than that desired following anodizing. For example, if the surface roughness following anodizing is specified as 14-18 μ-in, the surface finish prior to anodizing must be in the range of 6-10 μ-in.

However, due to excessive thermal cycling, movement within the grain structure of the aluminum base metal used to form the electrical assembly, and general anodic breakdown conditions, the anodized coating may become prone to cracking in leading to higher surface roughness conditions and leakage. This is especially of concern when a crack is radial in nature such as those that may form along the bottom of an o-ring groove. Such cracking may extend beyond the o-ring on both sides of the groove, creating a route for gas to transmigrate past the o-ring.

It may be advantageous therefore to provide an electrode which includes an anodized coating on all process surfaces other than the o-ring groove. Additionally, there may be advantage found in a method that provides an anodized coating on all process surfaces other than the o-ring groove.

### SUMMARY OF THE INVENTION

The present invention is directed to an electrode plate including an anodizing pattern having selected non-anodized surfaces. In one preferred embodiment of the invention, the electrode plate includes:
a) an electrode plate having an electrode plate interface surface,
b) a seat formed in the interface surface, and
c) the electrode plate including an anodized surface pattern having selected non-anodized surfaces.

In one preferred embodiment, a portion of the seat within which the seal is positioned is masked during an anodizing process to prohibit treatment and anodizing of the masked portion of the seat or o-ring groove.

The present invention is also directed to an electrode assembly including an anodizing pattern having selected non-anodized surfaces. In one preferred embodiment of the invention, the electrode assembly includes:
a) an electrode plate having an electrode plate interface surface,
b) a seat formed in the interface surface,
c) a seal positioned within the seat and compressible between the seat and a reactor mounting surface, and
d) the electrode plate including an anodized surface pattern having selected non-anodized surfaces.

The present invention is also directed to a method for producing an electrode plate including selectively anodized surfaces and selected non-anodized surfaces. In one preferred embodiment of the invention, the method for producing an electrode plate including selectively anodized surfaces and selected non-anodized surfaces includes the steps of:
a) forming an electrode plate having an interface surface, a seat formed on the interface surface, a seal positioned within the seat and compressible between the seat and a reactor mounting surface, and
b) masking a portion of the seat to provide a selected non-anodized portion of the electrode plate; and
c) selectively anodizing a portion of the electrode plate including an anodized surface pattern having selected non-anodized surfaces.

The present invention consists of the combination and arrangement of parts hereinafter more fully described, illustrated in the accompanying drawings and more particularly pointed out in the appended claims, it being understood that changes may be made in the form, size, proportions and minor details of construction without departing from the spirit or sacrificing any of the advantages of the invention.

### BRIEF DESCRIPTION OF THE FIGURES

FIG. 1 is a perspective representation of an electrode assembly according to one embodiment of the present invention;

FIG. 2 is a representation of an electrode assembly according to one embodiment of the present invention;

FIG. 3 is a side cutaway representation of an electrode assembly according to one embodiment of the present invention;

FIG. 4 is a detail side cutaway representation of an electrode assembly according to one embodiment of the present invention;

FIG. 5 is a detail side cutaway representation of an electrode assembly according to one embodiment of the present invention; and

FIG. 6 is a schematic flow chart representation of a method for producing an electrode plate including selectively anodized surfaces and selected non-anodized surfaces according to one embodiment of the present invention.

### DETAILED DESCRIPTION OF THE INVENTION

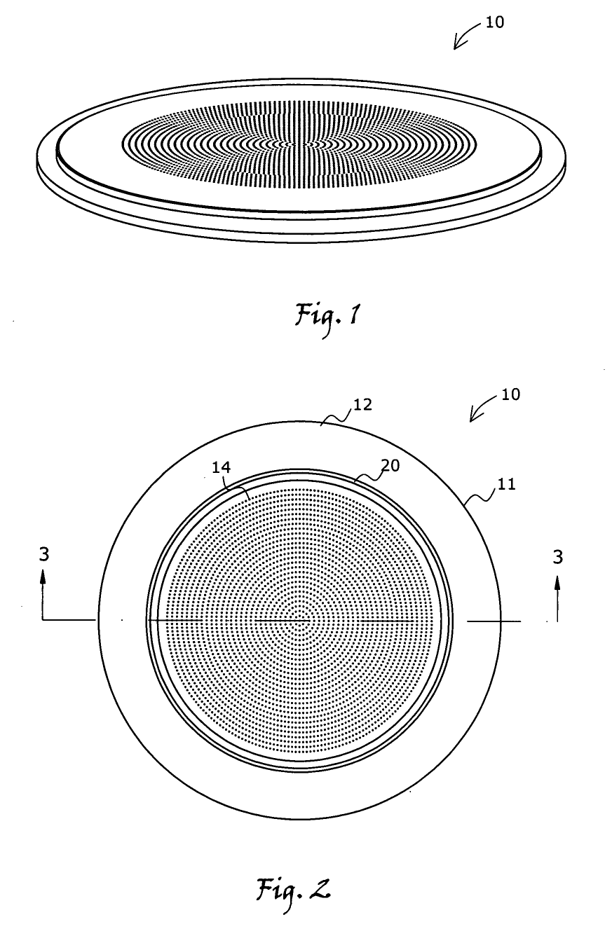

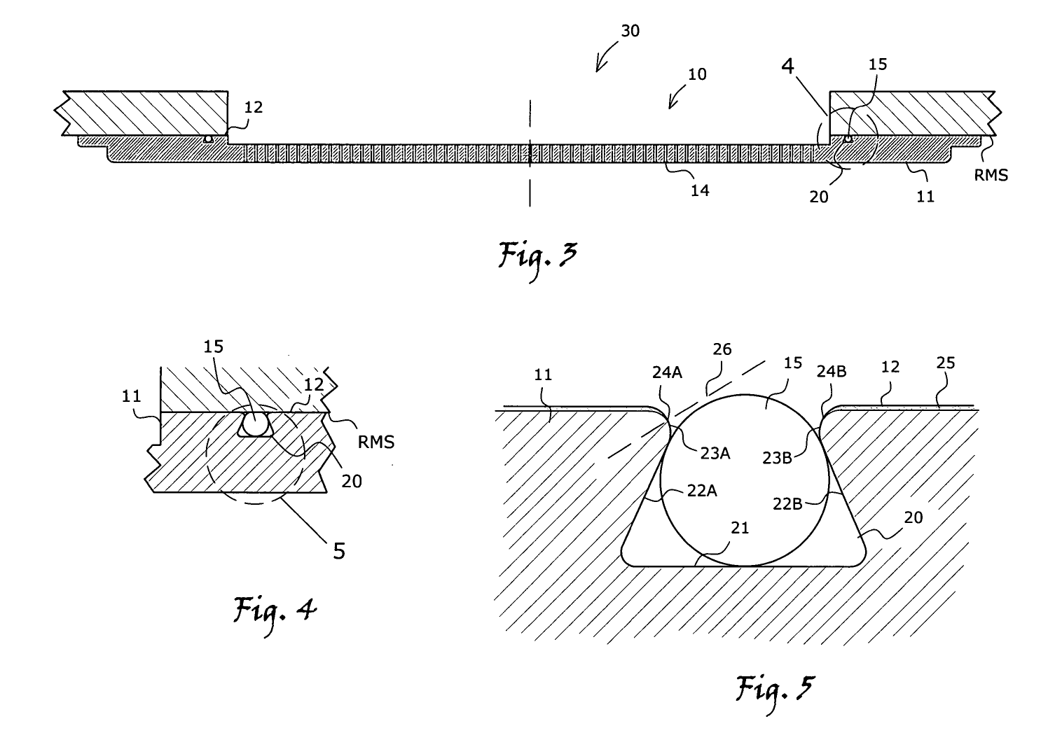

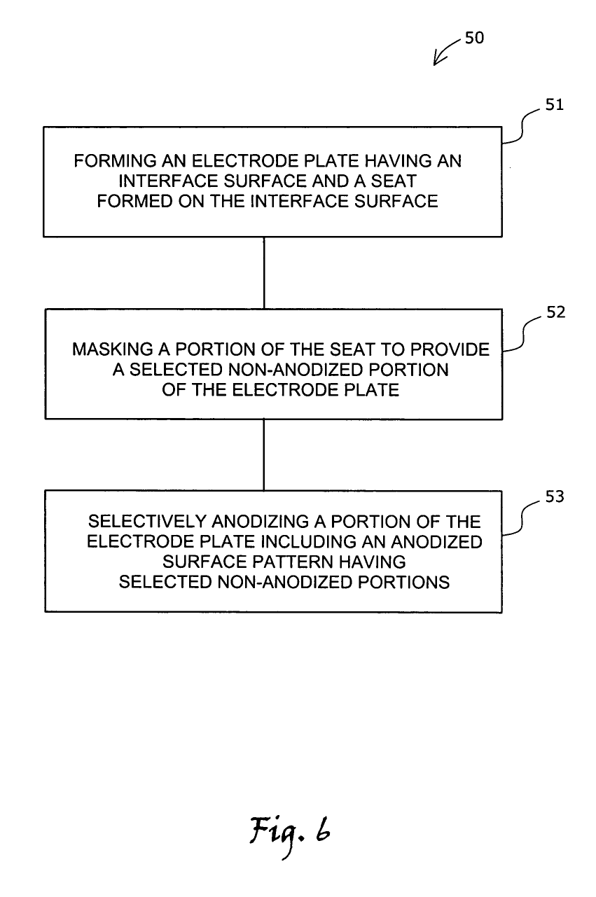

Referring to FIGS. 1 through 3, electrode 10 is shown to advantage. As seen in FIGS. 2 and 3, electrode 10 includes electrode plate 11 having a plurality of gas passages 14 formed through a cross-section of electrode plate 11. FIGS. 2 through 5 show electrode plate 11 including seat 20 formed in interface surface 12. FIG. 3 shows an electrode plate assembly 30 wherein electrode 10 mounted to a reactor mounting surface RMS. FIGS. 4 shows a detail of electrode 10 mounted to a reactor mounting surface RMS. Referring to FIGS. 3 and 4, seal 15 is positioned within seat 20 and is compressed between seat 20 and the reactor mounting surface RMS.

Referring to FIG. 5, seal 15, which in this instance comprises an o-ring, can be seen positioned in seat 20. Seat 20, which in this instance comprises an o-ring groove, includes bottom surface 21 from which sidewalls 22A and 22B extend. Upper radius 23A and upper radius 23B of seat 20 provide a transition between sidewalls 22A and 22B respectively.

As seen in FIG. 5, anodized coating 25 has been applied to interface surface 11 of electrode plate 10. Interface surface 11 of electrode plate 10 has been treated such that anodized coating 25 extends on either side of seat 20 to an apex 24A of upper radius 23A and apex 24B of upper radius 23B of o-ring groove 20. Referring to apex 24A of upper radius 23A, the apex is defined by an imaginary line 26 that bisects a plane parallel to interface surface 11 and a plane parallel to sidewall 22A. A remaining portion of seat 20 including a remaining lower adjacent portion of upper radius 23A and upper radius 23B, sidewalls 22A and 22B and bottom surface 21, is left untreated and therefore is shown without an anodized surface.

Referring to FIG. 6, a method for producing an electrode plate including selectively anodized surfaces and selected non-anodized surfaces 50 includes the steps of:
a) FORMING AN ELECTRODE PLATE HAVING AN INTERFACE SURFACE AND A SEAT FORMED ON THE INTERFACE SURFACE 51,
b) MASKING A PORTION OF THE SEAT TO PROVIDE A SELECTED NON-ANODIZED PORTION OF THE ELECTRODE PLATE 52; and
c) SELECTIVELY ANODIZING A PORTION OF THE ELECTRODE PLATE INCLUDING AN ANODIZED SURFACE PATTERN HAVING SELECTED NON-ANODIZED PORTIONS 53.

While this invention has been described with reference to the detailed embodiments, this is not meant to be construed in a limiting sense. Various modifications to the described embodiments, as well as additional embodiments of the invention, will be apparent to persons skilled in the art upon reference to this description. It is therefore contemplated that the appended claims will cover any such modifications or embodiments as fall within the true scope of the invention.

1. An electrode plate comprising:
an electrode plate interface surface;
a seat formed in the interface surface; and
the electrode plate including an anodized surface pattern having selected non-anodized surfaces.

2. The electrode plate of claim 1 further comprising a plurality of gas passages formed through a cross-section of the electrode plate.

3. The electrode plate of claim 1 further comprising a conductive interface surface.

4. The electrode plate of claim 1 wherein the sealing surface further comprises a recessed sealing surface.

5. The electrode plate of claim 1 wherein the sealing surface further comprises an o-ring groove.

6. The electrode plate of claim 1 wherein the selected non-anodized surfaces further comprise a portion of the seat.

7. The electrode plate of claim 1 wherein the selected non-anodized surfaces further comprises a portion of an o-ring groove located below an apex of a first upper radius of the o-ring groove and a second upper radius of the o-ring groove.

8. An electrode plate assembly comprising:
an electrode plate having an electrode plate interface surface;
a seat formed in the interface surface;
a seal positioned within the seat and compressible between the seat and a reactor mounting surface; and
the electrode plate including an anodized surface pattern having selected non-anodized surfaces.

9. The electrode plate assembly of claim 8 further comprising a plurality of gas passages formed through a cross-section of the electrode plate.

10. The electrode plate assembly of claim 8 further comprising a conductive interface surface.

11. The electrode plate assembly of claim 8 wherein the sealing surface further comprises a recessed sealing surface.

12. The electrode plate assembly of claim 8 wherein the sealing surface further comprises an o-ring groove.

13. The electrode plate assembly of claim 8 wherein the seal further comprises an o-ring.

14. The electrode plate assembly of claim 8 wherein the selected non- anodized surfaces further comprise a portion of the seat.

15. The electrode plate assembly of claim 8 wherein the selected non- anodized surfaces further comprises a portion of an o-ring groove located below an apex of a first upper radius of the o-ring groove and a second upper radius of the o- ring groove.

16. A method for producing an electrode plate including selectively anodized surfaces and selected non-anodized surfaces including the steps of:
forming an electrode plate having an interface surface, a seat formed on the interface surface, a seal positioned within the seat and compressible between the seat and a reactor mounting surface;
masking a portion of the seat to provide a selected non-anodized portion of the electrode plate; and
selectively anodizing a portion of the electrode plate including an anodized surface pattern having selected non-anodized portions.
